(19) United States
(12) Patent Application Publication
(10) Pub. No.: US 2017/0338350 A1
(43) Pub. Date: Nov. 23, 2017

(54) SEMICONDUCTOR DEVICE AND METHOD

(71) Applicant: GLOBALFOUNDRIES Inc., Grand Cayman (KY)

(72) Inventors: Stefan Flachowsky, Dresden (DE); Ralf Illgen, Dresden (DE)

(21) Appl. No.: 15/234,361

(22) Filed: Aug. 11, 2016

Related U.S. Application Data
(60) Provisional application No. 62/337,488, filed on May 17, 2016.

(51) Int. Cl. H01L 29/78; H01L 29/51; H01L 21/02; H01L 21/266; H01L 29/08; H01L 21/3115; H01L 21/28; H01L 29/66; H01L 29/423

(52) U.S. Cl. CPC H01L 29/78391; H01L 29/6684; H01L 29/66553; H01L 29/66545; H01L 29/6653; H01L 29/517; H01L 29/516; H01L 21/02181; H01L 29/42376; H01L 29/42364; H01L 29/0847; H01L 21/31155; H01L 21/28185; H01L 21/266; H01L 29/512

(57) ABSTRACT

The present disclosure provides a semiconductor device including a substrate, a gate structure formed over the substrate, the gate structure including a first ferroelectric material having a first remanent polarization and a second ferroelectric material having a second remanent polarization, the first remanent polarization being smaller than the second remanent polarization, and source and drain regions formed in the substrate, the source and drain regions being laterally separated by a channel region extending along a length direction below the gate structure, wherein the first ferroelectric material and the second ferroelectric material are stacked in a plane parallel to an upper surface of the substrate.

### BACKGROUND OF THE INVENTION

### 1. Field of the Invention

The present disclosure generally relates to a semiconductor device and to a method employed when fabricating a semiconductor device, and, more particularly, to ferroelectric FETs at advanced technology nodes to be used in non-volatile memory applications. Some aspects of the present disclosure relate to non-volatile memory cells with two or more bits per cell based on a ferroelectric FET.

### 2. Description of the Related Art

At present, semiconductor storage technologies represent some of the most commonly used data storage technologies. Semiconductor memory uses semiconductor-based circuit elements, such as transistors or capacitors, to store information, and common semiconductor memory chips may contain millions of such circuit elements. Both volatile and non-volatile forms of semiconductor memory exist. In modern computers, primary storage almost exclusively consists of dynamic volatile semiconductor memory or dynamic random access memory (DRAM). Since the turn of the century, a type of non-volatile semiconductor memory, known as flash memory, has steadily gained share as offline storage for home computers. Non-volatile semiconductor memory is also used for secondary storage in various advanced electronic devices and specialized computers.

The increasing demand for more mobility, higher integration density and lower power constantly drives the development of complex electronic devices, e.g., microchips, to the limits of current fabrication techniques. Particularly, the increased need of mobility, which is, for instance, driven by developments such as the internet of things (IoT), drives an increasing interest in non-volatile memory devices. Particularly, the market of flash memory technologies rapidly increased from a share in the market of 11% in 1998 to more than 32% in 2006. At the same time, the share of DRAM technology in the market decreased from 61% to 56% and continues to shrink. The tendency is unlikely to change because of the unchallenged performance advantages of non-volatile memories over current technologies, such as DRAM, with regard to write endurance, write voltage and power consumption.

A next-generation concept for reducing the costs per unit of storage and for compensating for larger bit error rates is considered to be based on multilevel cells (MLC), which represent memory elements capable of storing more than a single bit of information per cell. Particularly, MLC NAND flash is a flash memory technology using multiple levels per cell to allow more bits to be stored upon using the same number of transistors as in single level cells where each cell only stores a single bit of information.

Another effort to improve memory arrays is directed to ferroelectric gate field effect transistors (FeFETs). In general, ferroelectric materials have dielectric crystals which show a spontaneous electric polarization similar to ferromagnetic materials having a spontaneous magnetization. Upon applying an appropriate external electric field to a ferroelectric material, the direction of the polarization of the ferroelectric material may be reoriented by 180 degrees. The basic idea is to use the direction of spontaneous polarization in ferroelectric memories for storing digital bits. In FeFETs, the effect that one makes use of is the possibility to adjust the polarization state of a ferroelectric material on the basis of appropriate electrical fields which are applied to the ferroelectric material, which, in a FeFET, is usually the gate oxide. Since the polarization state of a ferroelectric material is preserved unless it is exposed to a high, with regard to the polarization state, counter oriented electrical field or a high temperature (“Curie temperature”), it is possible to “program” a capacitor formed of ferroelectric material such that an induced polarization state reflects an information unit. Therefore, an induced polarization state is preserved, even upon removing an accordingly “programmed” device from a power supply. In this way, FeFETs allow the implementation of non-volatile electrically switchable data storage devices.

On the basis of ferroelectric materials, it is possible to provide non-volatile memory devices, particularly random excess memory devices similar in construction to DRAM devices, but differing in that a ferroelectric layer is used instead of a dielectric layer such that a non-volatile memory device is obtained. For example, the 1T-1C storage cell design in a FeRAM is similar in construction to the storage cell in widely used DRAM in that both cell types include one capacitor and one excess transistor—a linear dielectric is used in a DRAM cell capacitor, whereas, in a FeRAM cell capacitor, the dielectric structure includes a ferroelectric material. Other types of FeRAMs are realized as 1T storage cells which consist of a single FeFET employing a ferroelectric dielectric instead of the gate dielectric of common MOSFETs. The current-voltage characteristic between source and drain of a FeFET depends in general on the electric polarization of the ferroelectric dielectric, i.e., the FeFET is in the on or off state, depending on the orientation of the electric polarization state of the ferroelectric dielectric. Writing on a FeFET is achieved in applying a writing voltage to the gate relative to source, while a 1T-FeRAM is read out by measuring the current when applying a reading voltage to source and drain. It is noted that reading out of a 1T-FeRAM is nondestructive.

Although a FeFET or a ferroelectric capacitor represent in theory very promising concepts for complex semiconductor devices, it is a difficult task to identify appropriate ferroelectric materials which are compatible with existing advanced manufacturing processes of complex devices, particularly at very small scales. For example, commonly known ferroelectric materials, such as PZT or perovskites, are not compatible with standard CMOS processes. According to present understanding, hafnium (Hf) based materials, which are used in current fabrication technologies, exhibit a para-electric behavior due to the predominantly monoclinic crystal structure present in hafnium oxide. However, recent research results indicate that dielectric materials on the basis of hafnium oxide may represent promising candidates for materials with ferroelectric behavior to be used in the fabrication of ferroelectric semiconductor devices. It is, for example, known that the monoclinic structure may be suppressed in hafnium oxide materials doped with zirconium (Zr), silicon (Si), yttrium (Y) or aluminum (Al), wherein the crystal structures of ferroelectric nature may be stabilized.

In view of the above discussion of the prior art, it is desirable to further improve the existing concepts. It is, for example, desirable to provide a non-volatile memory cell in MLC that allows further improving the integration density, power consumption and reliability of current memory devices.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

In a first aspect of the present disclosure, a semiconductor device is provided. In accordance with some illustrative embodiments herein, the semiconductor device includes a substrate, and a gate structure formed over the substrate, the gate structure including a first ferroelectric material having a first remanent polarization and a second ferroelectric material having a second remanent polarization, the first remanent polarization being smaller than the second remanent polarization, and source and drain regions formed in the substrate, the source and drain regions being laterally separated by a channel region extending along a length direction below the gate structure, wherein the first ferroelectric material and the second ferroelectric material are stacked in a plane parallel to an upper surface of the substrate.

In a second aspect of the present disclosure, a method is provided. In accordance with some illustrative embodiments herein, the method includes providing a substrate, providing a first ferroelectric material over the substrate, providing a second ferroelectric material adjacent to the first ferroelectric material, wherein the first ferroelectric material and the second ferroelectric material are stacked in a plane parallel to an upper surface of the substrate, and providing a gate electrode material over the first and second ferroelectric materials.

In a third aspect of the present disclosure, a method is provided. In accordance with some illustrative embodiments herein, the method includes providing a substrate, depositing a first ferroelectric material over the substrate, performing an implantation process, wherein dopants are implanted into a portion of the deposited first ferroelectric material for forming a portion of doped first ferroelectric material imbedded into the deposited first ferroelectric material, wherein the doped first ferroelectric material represents a second ferroelectric material being stacked with the first ferroelectric material in a plane parallel to an upper surface of the substrate, and providing a gate electrode material over the first and second ferroelectric materials.

In a fourth aspect of the present disclosure, a method is provided. In accordance with some illustrative embodiments herein, the method includes forming a hafnium oxide material layer over a substrate, the hafnium oxide material layer being formed over at least a first active region of the substrate, and performing an implantation process, wherein at least one of silicon (Si), zirconium (Zr), lanthanum (La), aluminum (Al), yttrium (Y) and gadolinium (Gd) is implanted into the first active region.

In a fifth aspect of the present disclosure, a method is provided. In accordance with some illustrative embodiments herein, the method includes applying a voltage signal to a gate of a semiconductor device, and coupling the source and the drain of the semiconductor device with ground. Herein, the semiconductor device includes a substrate, the gate structure formed over the substrate, the gate structure comprising a first ferroelectric material having a first remanent polarization and a second ferroelectric material having a second remanent polarization, the first remanent polarization being smaller than the second remanent polarization, and the source and drain regions formed in the substrate, the source and drain regions being laterally separated by a channel region extending along a length direction below the gate structure, wherein the first ferroelectric material and the second ferroelectric material are stacked in a plane parallel to an upper surface of the substrate. Herein, the voltage signal comprises at least a first voltage signal having a voltage peak exceeding a switching voltage at which the orientation of the second remanent polarization is flipped.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1h schematically illustrate four levels of a four level cell in accordance with some illustrative embodiments of the present disclosure;

FIGS. 2a-2b schematically illustrate in cross-sectional views a four level cell in accordance with some illustrative embodiments of the present disclosure;

FIGS. 3a-3b schematically illustrate in cross-sectional views a four level cell in accordance with other illustrative embodiments of the present disclosure;

FIGS. 4a-4e schematically illustrate in cross-sectional views a method of forming a four level cell in accordance with some illustrative embodiments of the present disclosure; and

FIGS. 5a-5i schematically illustrate in cross-sectional views a method of forming a four level cell in accordance with other illustrative embodiments of the present disclosure.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

The present disclosure relates to a method of forming a semiconductor device and to semiconductor devices, wherein the semiconductor devices are integrated on or in a chip. In accordance with some illustrative embodiments of the present disclosure, the semiconductor devices may substantially represent FETs, e.g., MOSFETs or MOS devices. When referring to MOS devices, the person skilled in the art will appreciate that, although the expression “MOS device” is used, no limitation to a metal-containing gate material and/or to an oxide-containing gate dielectric material is intended.

Semiconductor devices of the present disclosure concern devices which may be fabricated by using advanced technologies, i.e., the semiconductor devices may be fabricated by technologies applied to approach technology nodes smaller than 100 nm, for example, smaller than 50 nm or smaller than 35 nm. After a complete reading of the present application, the person skilled in the art will appreciate that, according to at least some aspects of the present disclosure, ground rules smaller or equal to 45 nm may be imposed. After a complete reading of the present application, the person skilled in the art will also appreciate that at least some aspects of the present disclosure proposes semiconductor devices with structures of minimal length dimensions and/or width dimensions smaller than 100 nm, for example, smaller than 50 nm or smaller than 35 nm. For example, in some applications the present disclosure may provide semiconductor devices fabricated by using 45 nm technologies or below, e.g., 28 nm or even below.

After a complete reading of the present application, the person skilled in the art will further appreciate that semiconductor devices may be fabricated as P-channel MOS transistors or PMOS transistors and N-channel transistors or NMOS transistors; both types of transistors may be fabricated with or without mobility-enhancing stressor features or strain-inducing features. It is noted that a circuit designer can mix and match device types, using PMOS and NMOS devices, stressed and unstressed, to take advantage of the best characteristics of each device type as they best suit the semiconductor device under design.

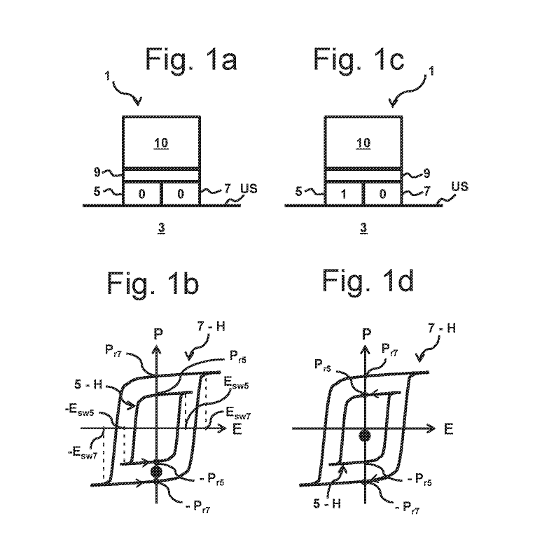

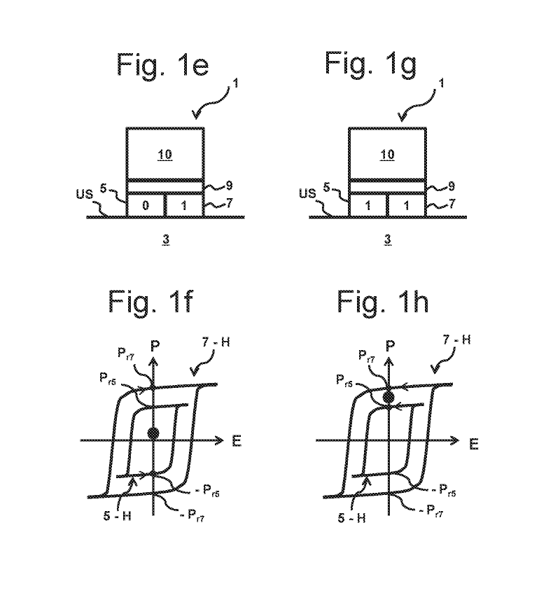

With regard to FIGS. 1a-1h, a semiconductor device will be described with regard to operational modes in accordance with some illustrative embodiments of the present disclosure. Particularly, FIGS. 1a, 1c, 1e and 1g schematically illustrate, in cross-sectional views, a semiconductor device in different operational modes. FIGS. 1b, 1d, 1f and 1h schematically illustrate P-E diagrams corresponding to the semiconductor device as depicted in the respective FIGS. 1a, 1c, 1e, 1g with regard to different operational modes. The P-E diagrams represent hysteresis loops and, therefore, indicate the ferroelectric nature of the semiconductor devices.

In accordance with some illustrative embodiments of the present disclosure, the semiconductor devices, as schematically illustrated in FIGS. 1a, 1c, 1e and 1g, schematically show ferroelectric FETs or FeFETs implementing a four level cell structure for a non-volatile memory cell.

FIGS. 1a, 1c, 1e and 1g each show a gate structure 1 formed over a substrate 3. The substrate 3 may be, for example, a bulk substrate or may represent an active layer of a semiconductor-on-insulator (SOI) substrate or silicon/germanium-on-insulator (SGOI) substrate. In general, the term “substrate” may be understood to cover all kinds of substrates known in the art and employed in the fabrication of semiconductor devices, particularly semiconductor substrates and semiconducting substrates. The person skilled in the art will appreciate that no limitation to a special kind of substrate is intended.

In accordance with some illustrative embodiments of the present disclosure, the gate structure 1 may comprise a gate dielectric comprising a first ferroelectric material 5 and a second ferroelectric material 7, wherein the first ferroelectric material 5 and the second ferroelectric material 7 are stacked in a plane parallel to an upper surface “US” of the substrate 3. In accordance with some illustrative examples herein, the first ferroelectric material 5 may have a first remanent polarization that is substantially smaller than a second remanent polarization associated with the second ferroelectric material 7.

In accordance with some illustrative embodiments of the present disclosure, a gate electrode material 10, e.g., polysilicon, amorphous silicon or a gate metal material as conventionally employed in the fabrication of MOSFETs, is disposed over the gate dielectric.

In accordance with some illustrative embodiments of the present disclosure, a work function adjusting material 9 may be interposed between the gate electrode material 10 and the gate dielectric. For example, the work functional adjusting material 9 may comprise titanium nitride (TiN) and the like.

After a complete reading of the present application, the person skilled in the art will appreciate that the gate dielectric may further comprise, in addition to the first and second ferroelectric materials 5, 7, a high-k material, such as hafnium oxide, hafnium oxynitride, silicon oxide, and the like.

In accordance with some illustrative embodiments of the present disclosure, the first and second ferroelectric materials may have a thickness in a range from about 7-10 nm. However, the person skilled in the art will appreciate that this does not pose any limitation to the present disclosure and ferroelectric materials having a different thickness, as explicitly defined herein, may be considered.

In accordance with some illustrative embodiments, the gate structure 1 may implement a number of polarization combinations associated with the first and second ferroelectric materials 5, 7, i.e., “00”, “10”, “01”, “11”. Accordingly, a four level cell structure may be implemented.

In accordance with some illustrative embodiments of the present disclosure, FIG. 1a shows the gate structure 1 in an operational mode having the polarization combination “00”, according to which the first ferroelectric material 5 has polarization “0” and the second ferroelectric material 7 has polarization “0”. FIG. 1c shows the gate structure 1 in an operational mode having the polarization combination “10”, according to which the first ferroelectric material 5 has polarization “1” and the second ferroelectric material 7 has polarization “0”. FIG. 1e shows the gate structure 1 in an operational mode having the polarization combination “01”, according to which the first ferroelectric material 5 has polarization “0” and the second ferroelectric material 7 has polarization “1”. FIG. 1g shows the gate structure 1 in an operational mode having the polarization combination “11” according to which the first ferroelectric material 5 has polarization “1” and the second ferroelectric material 7 has the polarization “1”.

The person skilled in the art will appreciate that each of the states “00”, “10”, “01”, “11” can store a charge equivalent to a single bit DRAM cell charge. The person skilled in the art will appreciate that the semiconductor device as described above may implement the combination of two single bit cells.

Regarding the states which are indicated by “0” or “1” in FIGS. 1a, 1c, 1e and 1g for the first and second ferroelectric materials 5, 7, these states indicate opposite directions in which remanent polarizations (that is, the polarizations that remain at zero external electric field) are oriented. Particularly, the state “0” may be associated with a polarization orientation within an associated ferroelectric material such that the FeFET comprising this ferroelectric material is in the “off” state. Accordingly, the state “1” indicates an orientation of the remanent polarization of an associated ferroelectric material in which the FeFET under consideration is in the “on” state. However, this does not pose any limitation to the present disclosure and the person skilled in the art will appreciate that an assignment of the states “0”, “1” to a particular orientation of the polarization within a ferroelectric material of a FeFET is arbitrary, but once a particular assignment is chosen, the assignment is to be maintained for consistency. The present disclosure is not confined to a particular assignment and the chosen assignment is only used for illustrative purposes and is not intended to limit the present disclosure by any means.

FIGS. 1b, 1d, 1f and 1h each show a P-E diagram where the polarization P is plotted against the electrical field E acting on the first and second ferroelectric materials 5, 7 (the electric field E is related to the voltage applied to the gate electrode when 0 V are applied to source and drain). The ferroelectric nature of the first and second ferroelectric materials 5, 7 is represented in the P-E diagrams by hysteresis loops, i.e., a hysteresis loop 5-H representing the behavior of the first ferroelectric material 5, while a hysteresis loop 7-H is associated with the second ferroelectric material 7. According to the hysteresis loop 5-H, decreasing the electrical field E from a maximum value at which the polarization is saturated (that is, maximized) to zero, the polarization only slightly decreases to a remanent polarization Pᵣ₅ at an electrical field equal to zero. Upon further decreasing the electrical field E to a coercive field strength (field E at which the polarization vanishes), the polarization P rapidly decreases to zero. When reaching the negative maximum value of E at which the polarization is saturated (that is, maximized), the polarization P of the first ferroelectric material 5 reaches a negative maximum value when the first ferroelectric material 5 is completely polarized. Upon increasing the electrical field E again to zero, the polarization P slightly increases to a remanent polarization of −Pᵣ₅, and upon reaching the respective coercive field strength, the polarization P increasingly strives against zero. When further increasing the electrical field E to the maximum value at which the polarization is saturated (that is, maximized), the maximum polarization of the first ferroelectric material 5 is reached in saturation.

The hysteresis loops 5-H, 7-H show a peculiar behavior, that is, as long as the electric field is not raised/lowered beyond a switching field strength (−E_{sw5}, E_{sw5} in case of 5-H, −E_{sw7}, E_{sw7} in case of 7-H) when coming from the negative maximum value/positive maximum value, upon removing the electric field (E to 0), the remanent polarization state is not changed. However, upon exceeding the switching field strength in one direction, upon removing the electric field, the remanent polarization state is mirrored with regard to the axis of the electric field E (i.e., the sign of the remanent polarization is flipped).

FIG. 1b indicates the P-E diagram in a writing operation for writing the states “0”, “0” into the first and second ferroelectric materials 5, 7. In order to write the “0” into the first and second ferroelectric materials 5, 7, a voltage signal is applied to the gate structure 1, the voltage signal having a voltage peak smaller than −E_{sw7}.

In accordance with some illustrative embodiments of the present disclosure, the voltage signal may be a rectangular voltage-time-signal, wherein a voltage lower than −E_{sw7} (e.g. −5 V in case of the second ferroelectric material 7 having a switching voltage of ±4 V) for a sufficient time duration that the maximum polarization or saturation polarization in the third quadrant of the P-E diagram is achieved. Due to the finite voltage pulse, the remanent polarizations −Pᵣ₅ and −Pᵣ₇ are reached when zero volts are applied to the gate structure 1 at the end of the voltage signal. Accordingly, without dependence on previous remanent polarization states of the first and second ferroelectric materials, the remanent polarization states “0” and “0” are written into the first and second ferroelectric materials 5, 7.

The arrows in the hysteresis loops 5-H and 7-H in the third quadrant of the hysteresis loops 5-H and 7-H indicate that the polarization strives against the respective remanent polarizations at the end of the voltage pulse.

FIG. 1d schematically illustrates the P-E diagram in the case of a writing operation for writing a “1” into the first ferroelectric material 5, and a “0” in the second ferroelectric material 7. In accordance with some illustrative embodiments of the present disclosure, a voltage signal comprising two voltage pulses are applied to the gate structure 1.

In accordance with some illustrative embodiments, the voltage signal may, for example, comprise a first voltage pulse having a voltage peak at a voltage leading to an electric field exceeding the switching field −E_{sw7} (for example, −5 V in the case of the second ferroelectric material having a switching voltage of ±4 V), and a subsequent second voltage signal having a voltage peak leading to an electric field exceeding E_{sw5} (for example, +3 V in case of the first ferroelectric material 5 having a switching voltage of ±2 V). The two voltage signals may be separated by at least one intermediate voltage level smaller than a voltage corresponding to E_{sw5} for a limited time interval, such as 0 V, or the second voltage signal may directly follow the first voltage signal without intermediate voltage level.

The arrows in the hysteresis loops 5-H and 7-H of FIG. 1d indicate that the polarization of the first ferroelectric material 5 strives against the remanent polarization Pᵣ₅, and that the polarization of the second ferroelectric material 7 strives against the remanent polarization −P_{c} due to the voltage peak at a voltage corresponding to an electric field higher than E_{sw5}.

FIG. 1f schematically illustrates the P-E diagram in the case of a writing operation for writing a “0” into the first ferroelectric material 5, and a “1” in the second ferroelectric material 7. In accordance with some illustrative embodiments of the present disclosure, a voltage signal comprising two voltage pulses are applied to the gate structure 1.

In accordance with the writing operation as described above, the person skilled in the art will appreciate that, in accordance with some illustrative embodiments herein, a voltage signal may be applied to the gate structure 1, and source and drain (not illustrated) may be coupled with ground, wherein the voltage signal comprises at least a first voltage signal having a voltage peak exceeding a switching voltage at which the orientation of the second remanent polarization Pᵣ₇ is flipped (that is, an electric field exceeding E_{sw7} acts on the first and second ferroelectric materials 5, 7). In some special illustrative embodiments herein, the voltage signal may further comprise a second voltage signal having a voltage peak exceeding a switching voltage at which the orientation of the first remanent polarization Pᵣ₅ is flipped (that is, an electric field exceeding E_{sw5} acts on the first and second ferroelectric materials 5, 7).

In accordance with some illustrative embodiments, the voltage signal may, for example, comprise a first voltage pulse having a voltage peak at a voltage leading to an electric field exceeding the switching field E_{sw7} (for example, 5 V in the case of the second ferroelectric material having a switching voltage of ±4 V), and a subsequent second voltage signal having a voltage peak leading to an electric field exceeding −E_{sw5} (for example, −3 V in case of the first ferroelectric material 5 having a switching voltage of ±2 V). The two voltage signals may be separated by at least one intermediate negative voltage level greater than a voltage corresponding to −E_{sw5} for a limited time interval, such as 0 V, or the second voltage signal may directly follow the first voltage signal without intermediate voltage level.

The arrows in the hysteresis loops 5-H and 7-H of FIG. 1f indicate that the polarization of the first ferroelectric material 5 strives against the remanent polarization −Pᵣ₅, and that the polarization of the second ferroelectric material 7 strives against the remanent polarization Pᵣ₇ due to the voltage peak at a voltage corresponding to an electric field lower than −E_{sw5}.

FIG. 1h indicates the P-E diagram in a writing operation for writing the states “1”, “1” into the first and second ferroelectric materials 5, 7. In order to write the “1” into the first and second ferroelectric materials 5, 7, a voltage signal is applied to the gate structure 1, the voltage signal having a voltage peak higher than E_{sw7}.

After a complete reading of the present application, the person skilled in the art will appreciate that the big bullets as depicted in the FIGS. 1b, 1d, 1f and 1h refer to the total “effective” polarization of the semiconductor device shown in FIGS. 1a, 1c, 1e and 1g resulting from the superposition of the remanent polarizations Pr5 and Pr7 of the first and second ferroelectric materials 5, 7. The big bullets represent the different states the memory can be in, four memory states in the present case of FIGS. 1b, 1d, 1f and 1h. The semiconductor device as illustrated in FIGS. 1a, 1c, 1e and 1g shows an example of a multilevel FeFET device, i.e., a four-level FeFET device.

In accordance with some illustrative embodiments of the present disclosure, the voltage signal may be a rectangular voltage-time-signal, wherein a voltage lower than E_{sw7} (e.g., 5 V in case of the second ferroelectric material 7 having a switching voltage of ±4 V) for a sufficient time duration that the maximum polarization or saturation polarization in the third quadrant of the P-E diagram is achieved. Due to the finite voltage pulse, the remanent polarizations Pᵣ₅ and Pᵣ₇ are reached when zero volts are applied to the gate structure 1 at the end of the voltage signal. Accordingly, without dependence on previous remanent polarization states of the first and second ferroelectric materials, the remanent polarization states “1” and “1” are written into the first and second ferroelectric materials 5, 7.

The arrows in the hysteresis loops 5-H and 7-H in the first quadrant of the hysteresis loops 5-H and 7-H indicate that the polarization strives against the respective remanent polarizations at the end of the voltage pulse.

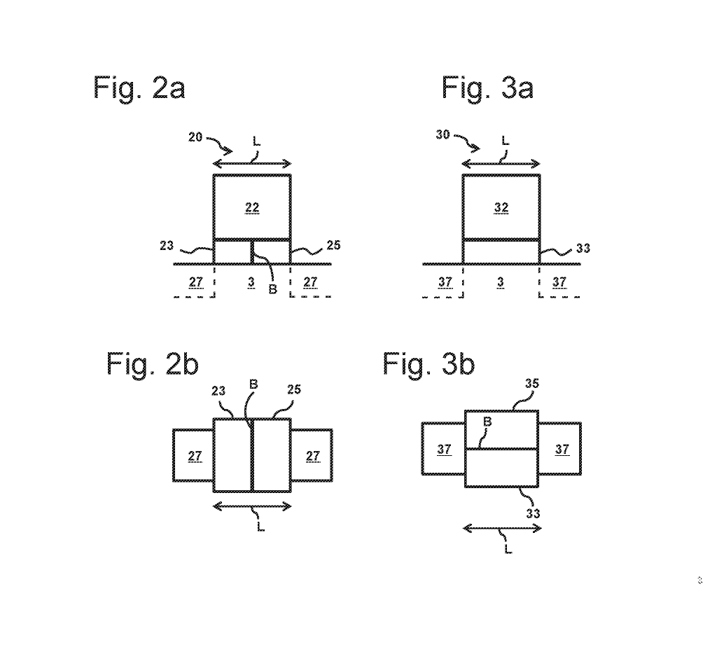

With regard to FIGS. 2a and 2b, a semiconductor device in accordance with some illustrated embodiments of the present disclosure will be described. FIG. 2a schematically shows, in a cross-sectional view according to which the plane is parallel to a normal of an upper surface of a substrate 3 (this substrate is similar to the substrate 3 as described above with regard to FIG. 1 and for this reason denoted with the same reference numeral).

In accordance with some illustrative embodiments of the disclosure, the semiconductor device comprises a gate structure 20 formed over the substrate 3, wherein the gate structure 20 comprises a gate electrode material 22, a first ferroelectric material 23 having a first remanent polarization, and a second ferroelectric material 25 having a second remanent polarization different from the first remanent polarization. In accordance with some illustrative embodiments herein, the first and second remanent polarizations may correspond to the remanent polarizations of the first and second ferroelectric materials 5, 7 as described above with regard to FIGS. 1a-1h.

With regard to FIGS. 2a and 2b, the semiconductor device further comprises source and drain regions 27 formed in the substrate 3. The source and drain regions 27 are separated by a channel region which extends along a length direction of the gate structure 20 below the gate structure 20 in the substrate 3. Particularly, the length direction, as indicated by double arrow L in FIGS. 2a and 2b, corresponds to a direction of charge carriers flowing through the channel region in an “on” state of the semiconductor device.

Referring to FIG. 2a, the first ferroelectric material 23 and the second ferroelectric material 25 are stacked in a plane parallel to an upper surface of the substrate. That is, along the length direction L, the first and second ferroelectric materials 23, 25 are arranged one behind the other. Particularly, a boundary B between the first and second ferroelectric materials 23, 25 is oriented across the length direction L, e.g., perpendicular to the length direction L.

FIG. 2b schematically illustrates a top view on the first and second ferroelectric materials 23, 25 and the source and drain regions 27. The boundary B is oriented to lay across the length direction L, for example, the boundary B may be oriented perpendicular relative to the length direction L.

With regard to FIGS. 3a and 3b, semiconductor devices in accordance with other illustrative embodiments of the present disclosure will be described. FIG. 3a shows a semiconductor device comprising the substrate 3 (similar to the substrate 3 as described above with regard to FIGS. 1a-1h and 2a-2b), and a gate structure 30 formed over the substrate 3, wherein the gate structure 30 comprises a first ferroelectric material 33 having a first remanent polarization, and source and drain regions 37 formed in the substrate 3 adjacent to the gate structure 30, wherein the source and drain regions 37 are separated by a channel region extending along a length direction L below the gate structure 30. In the cross-sectional view as depicted in FIG. 3a, the first ferroelectric material completely extends below a gate electrode material 32 of the gate structure 30 along the length direction L.

With regard to FIG. 3b, a top view of the first ferroelectric material 33 and a second ferroelectric material 35 is shown, wherein the second ferroelectric material 35 is provided adjacent to the first ferroelectric material 33 in between the source and drain region 37. The first ferroelectric material 33 and the second ferroelectric material 35 are again stacked in a plane parallel to an upper surface of the substrate 3, and a boundary B between the first and second ferroelectric materials 35 is oriented in parallel with regard to the length direction L.

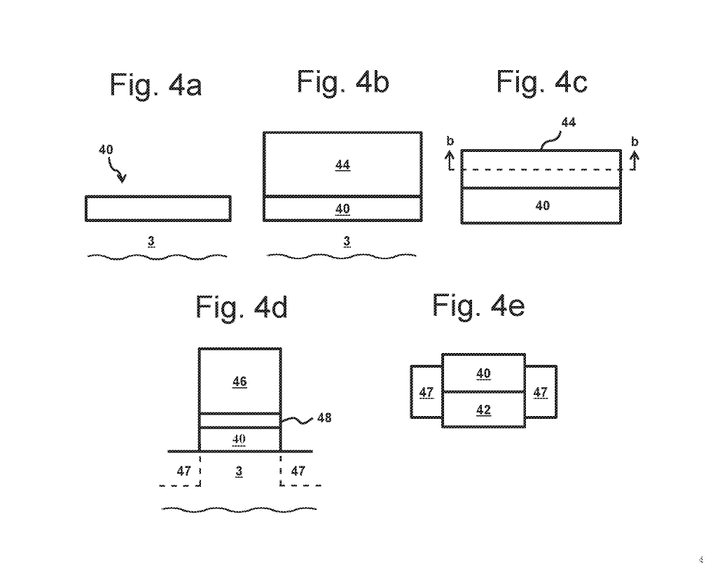

With regard to FIGS. 4a-4e, a method is described below. In accordance with some illustrative embodiments of the present disclosure, the method may be employed for forming a semiconductor device as described herein with regard to some illustrative embodiments.

FIG. 4a schematically illustrates a semiconductor device at an early stage during fabrication, wherein a substrate 3 is provided and a first ferroelectric material 40 is provided over the substrate 3. The substrate 3 may be provided in accordance with the substrate 3 described above with regard to FIGS. 1a-1h, 2a-2b and 3a-3b. Providing the first ferroelectric material 40 may comprise forming the first ferroelectric material 40 over the substrate 3, for example, by depositing a doped hafnium oxide material via atomic layer deposition (ALD), e.g. hafnium oxide doped with at least one of Si, Zr, La, Al, Y and Gd, and inducing the ferroelectric phase in the deposited material by means of an appropriate annealing step. Alternatively, the first ferroelectric material 40 may be formed by depositing a rare earth modified hafnium thin film via sequential pulsed laser deposition (SPLD) techniques. In some illustrative examples herein, ferroelectric rare earth doped Sm:HfO₂ (SHO) and Gd:HfO₂ (GHO) thin films may be fabricated as the first ferroelectric material 40.

With regard to FIG. 4b, a more advanced stage of the method is schematically illustrated in a cross-sectional view, where a masking pattern 44 partially covering an upper surface of the first ferroelectric material 40 is formed. With regard to FIG. 4c, a top view of the accordingly patterned first ferroelectric material 40 is illustrated, wherein the cross-section taken in FIG. 4b is indicated by the broken line b-b.

In accordance with some illustrative embodiments of the present disclosure, an implantation process (not illustrated) is performed for implanting dopants into the exposed first ferroelectric material 40. The implanted dopants change the ferroelectric behavior of the first ferroelectric material, e.g., the remanent polarization of the first ferroelectric material may be increased or decreased. In accordance with some special illustrative examples herein, by implanting dopants, the remanent polarization of the first ferroelectric material 40 may be increased. For example, dopants may be selected among Si, Zr, La, Al, Y and Gd.

FIG. 4d schematically illustrates the method at a more advanced stage during fabrication, after the masking pattern 44 is removed and a gate stack comprising a gate electrode material 46 and an optional work function adjusting material 48, e.g., TiN, is formed on the lateral bi-layer stack provided in the method of FIGS. 4a-4c. As a result of the implantation process, the first exposed ferroelectric material 40 subjected to the implantation is transformed into a second ferroelectric material 42. The semiconductor device, as illustrated in FIG. 4d, may further comprise source and drain regions 47 formed in the substrate 3 in alignment with the gate stack. The source and drain regions 47 are laterally separated by a channel region extending along a length direction below the gate stack or gate structure comprising the ferroelectric materials 40, 42, the gate electrode material 46 and the work function adjusting material 48.

In accordance with FIG. 4e, a cross-sectional top view of the first ferroelectric material 40 and the second ferroelectric material 42, together with the source and drain regions 47 is shown. The first ferroelectric material 40 and the second ferroelectric material 42 are stacked in a plane parallel to an upper surface of the substrate 3.

In accordance with some illustrative embodiments of the present disclosure, the first ferroelectric material 40 and the second ferroelectric material 42 may each completely extend below the gate electrode material 46 along the length direction. However, this does not pose any limitation on the present disclosure, and the person skilled in the art will appreciate that, upon appropriately orienting the masking pattern 44 in FIG. 4c, a configuration corresponding to the embodiments as described above with regard to FIGS. 2a and 2b may be formed.

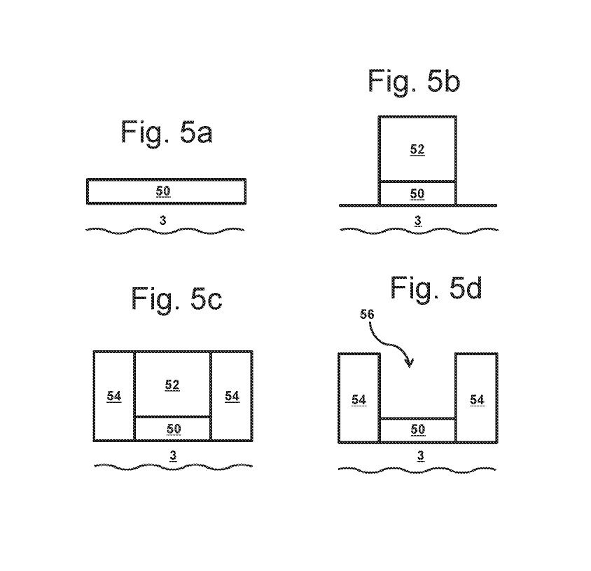

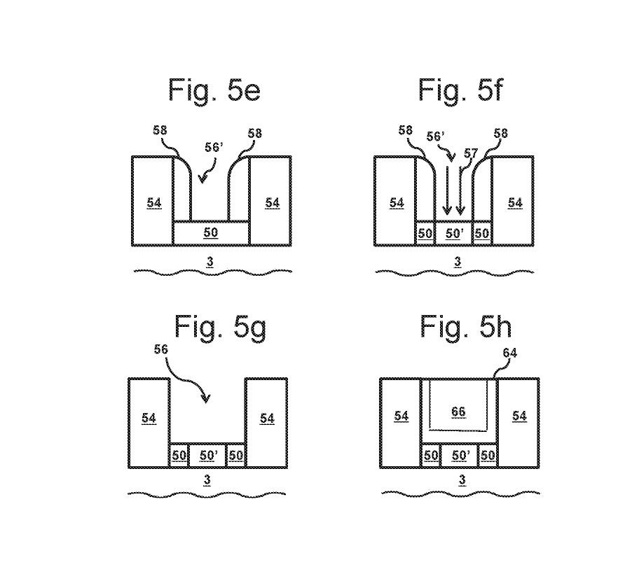

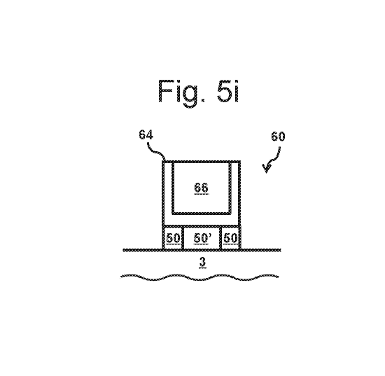

With regard to FIGS. 5a-5i, a method in accordance with other illustrative embodiments of the present disclosure will be described. With regard to FIG. 5a, a semiconductor device is schematically illustrated in a cross-sectional view at a very early stage during fabrication, after a substrate 3 (similar to the substrate 3 described above with regard to FIGS. 1a-4e) is provided, and a first ferroelectric material 50 is provided on the substrate 3. After a complete reading of the present disclosure, the person skilled in the art will appreciate that the first ferroelectric material 50 may be provided over the substrate 3 in accordance with techniques as described above with regard to FIG. 4a.

FIG. 5b schematically illustrates the semiconductor device at a more advanced stage during fabrication, after a dummy gate is formed, the dummy gate comprising a dummy gate material 52 and the first ferroelectric material 50, which may be patterned in accordance with the dummy gate material 52. In accordance with some illustrative embodiments of the present disclosure, the dummy gate material 52 may be a silicon material, such as polysilicon or amorphous silicon and the like.

With regard to FIG. 5c, the semiconductor device is schematically illustrated at a more advanced stage during fabrication, after a spacer structure 54 is formed adjacent to the dummy gate, the spacer structure 54 covering sidewalls of the dummy gate 52. In accordance with some illustrative embodiments of the present disclosure, the spacer structure 54 may be a dummy-fill provided adjacent to the dummy gate structure, particularly in between the illustrated dummy gate structure and adjacent not illustrated dummy structures. Accordingly, the dummy gate may be laterally enclosed by the dummy-fill/spacer structure 54.

With regard to FIG. 5d, the semiconductor device is schematically illustrated at a more advanced stage during fabrication, after the dummy gate material 52 is selectively removed and a gate trench 56 defined by the dummy-fill/spacer structure 54 is provided. The gate trench 56 exposes an upper surface of the first ferroelectric material 50.

FIG. 5e schematically illustrates the semiconductor device at a more advanced stage during fabrication, after a spacer structure 58, e.g., a spacer liner, is formed in the gate trench 56, partially covering an upper surface of the first ferroelectric material 50 and partially exposing an upper surface of the first ferroelectric material 50, wherein a gate trench 56′ having a smaller opening area is formed. In accordance with some illustrative embodiments of the present disclosure, the spacer structure 58 may be formed by one of silicon nitride and silicon oxide, which may be deposited and anisotropically etched, resulting in the spacer structure 58.

With regard to FIG. 5f, the semiconductor device is schematically illustrated at a more advanced stage during fabrication, when an implantation process 57 is performed in alignment with the spacer structure 54 and the spacer structure 58. The implantation process 57 may be similar to the implantation process as described above with regard to FIGS. 4a-4e.

In accordance with some illustrative embodiments of the present disclosure, the first ferroelectric material 50 may be transformed by the implantation process into a second ferroelectric material 50′, having a different remanent polarization than the first ferroelectric material 50, such as a substantially higher or lower remanent polarization when compared to the first ferroelectric material 50, together with an optional anneal process (not illustrated). In accordance with some illustrative embodiments herein, the second ferroelectric material 50′ may have a substantially higher remanent polarization when compared to the first ferroelectric material 50.

FIG. 5g schematically illustrates the semiconductor device at a more advanced stage during fabrication, after the implantation 57 is completed and the spacer structure 58 is removed. Herein, the gate trench 56 is restored and an upper surface of the first ferroelectric material 50 is exposed. Accordingly, a lateral tri-layer stack (“lateral” indicating a direction in a plane parallel to an upper surface of the substrate 3) is provided.

FIG. 5h schematically illustrates the semiconductor device at a more advanced stage during fabrication, after the gate trench 56 is filled with a gate electrode material 66, e.g., polysilicon, amorphous silicon or a conventional gate electrode metal. Optionally, a work function adjusting material 64 may be deposited prior to filling the trench 56 with the gate electrode material 66. In accordance with some illustrative examples herein, the optional work function adjusting material 64 may be conformally deposited. In accordance with some special examples, the work function adjusting material layer 56 may comprise TiN. After a complete reading of the present disclosure, the person skilled in the art will appreciate that, by conformally depositing the optional work function adjusting material 64, a U-shaped work function adjusting material 64 may be provided in the gate trench 56. Alternatively, the work function adjusting material 64 may be only formed in the gate trench 56 by covering an upper surface of the first and second ferroelectric materials 50, 50′ and only partially covering exposed inner sidewalls of the dummy-fill/spacer structure 54. However, a U-shaped work function adjusting material 64 may reliably encapsulate the gate electrode material 66.

FIG. 5i schematically illustrates the semiconductor device at a more advanced stage during fabrication, after the dummy fill/spacer structure 54 is removed and a gate structure 60 comprising the first and second ferroelectric materials 50, 50′, and the gate electrode material 66 (together with the optional work function adjusting material 64) is exposed.

Subsequently, processing may be continued in accordance with known FEOL processing for implanting source/drain regions adjacent to the gate structure 60, and so on. Accordingly, the first ferroelectric material 50 laterally encloses the second ferroelectric material 50′

With regard to the implantation processes described above for transforming the first ferroelectric material into the second ferroelectric material, the implantation processes may comprise implanting at least one of Si, Zr, La, Al, Y and Gd into a first ferroelectric material, together with an optional anneal process (not illustrated). In accordance with some special illustrative examples herein, the first ferroelectric material may be a ferroelectric hafnium oxide material. In special illustrative examples, the implantation process may comprise implanting silicon at an implantation dose of about 1e16 atoms/cm².

In accordance with some illustrative embodiments of the present disclosure, the first ferroelectric material may have a switching voltage of ±2 V, and the second ferroelectric material may have a switching voltage of ±4 V. Voltage signals for writing bits into the disclosed four level bit cells may have voltage peaks at ±5 V for writing “0”, “0” or “1”, “1” (depending on the sign of the voltage peak), while voltage signals used for writing “0”, “1” or “1”, “0”, comprise a combination of voltage signals having peaks at ±5 V and ±3 V (depending on the sign). After a complete reading of the present disclosure, the person skilled in the art will appreciate that the disclosed explicit values for the switching voltages and the voltage peaks are not particularly limiting, as long as the voltage peaks are higher than the switching voltages, and the first and second ferroelectric materials have different switching voltages (and different remanent polarizations).

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

What is claimed:

1. A semiconductor device, comprising:
a substrate;
a gate structure formed over said substrate, said gate structure comprising a first ferroelectric material having a first remanent polarization and a second ferroelectric material having a second remanent polarization, said first remanent polarization being smaller than said second remanent polarization; and
source and drain regions formed in said substrate, said source and drain regions being laterally separated by a channel region extending along a length direction below said gate structure;
wherein said first ferroelectric material and said second ferroelectric material are stacked in a plane parallel to an upper surface of said substrate.

2. The semiconductor device of claim 1, wherein said first and second ferroelectric materials are stacked along a direction parallel to said length direction.

3. The semiconductor device of claim 2, wherein one of said first ferroelectric material and said second ferroelectric material is interposed between two regions formed by said other of said first ferroelectric material and said second ferroelectric material.

4. The semiconductor device of claim 3, wherein said gate structure further comprises a gate electrode material and a work function adjusting material of a substantially U-shape, said work function adjusting material separating said gate electrode material from said first and second ferroelectric materials.

5. The semiconductor device of claim 1, wherein said first and second ferroelectric materials are stacked along a direction across said length direction.

6. The semiconductor device of claim 1, wherein said first ferroelectric material switches its polarization state at a switching voltage of about ±2 V or less, and said second ferroelectric material switches its polarization state at a switching voltage having an absolute value of substantially greater than about 2 V.

7. The semiconductor device of claim 1, wherein said first ferroelectric material comprises a hafnium oxide material having first dopants, and said second ferroelectric material comprises a hafnium oxide material having second dopants different from said first dopants.

8. The semiconductor device of claim 1, wherein a thickness of said first and second ferroelectric material is in a range from about 7-10 nm.

9. The semiconductor device of claim 1, wherein one of said first and second ferroelectric materials comprises a hafnium oxide material doped with silicon at a mole fraction in a range from about 0.02-0.04.

10. A method, comprising:
forming a first ferroelectric material over a substrate;
forming a second ferroelectric material adjacent said first ferroelectric material, wherein said first ferroelectric material and said second ferroelectric material are stacked in a plane parallel to an upper surface of said substrate; and
forming a gate electrode material over said first and second ferroelectric materials.

11. The method of claim 10, wherein forming said first and second ferroelectric materials comprises:
depositing said first ferroelectric material over said substrate;
forming a masking pattern over said deposited first ferroelectric material, said masking pattern leaving an upper surface portion of said deposited first ferroelectric material partially exposed;
performing an implantation process in accordance with said masking pattern, wherein dopants are implanted into a portion of said first ferroelectric material in alignment with said masking pattern, said doped portion of said first ferroelectric material forming said second ferroelectric material;
removing said masking pattern; and
forming a gate electrode over said first and second ferroelectric materials.

12. The method of claim 11, wherein said first ferroelectric material comprises a hafnium oxide material, and wherein said implantation process comprises implanting at least one of silicon (Si), zircominum (Zr) and titanium (Ti).

13. The method of claim 12, wherein performing said implantation process comprises implanting silicon at an implantation dose of about 1e16 atoms/cm².

14. The method of claim 10, further comprising, prior to forming said second ferroelectric material:
forming a dummy gate over said first ferroelectric material;
forming a dummy-fill adjacent to said dummy gate structure, said dummy-fill laterally enclosing said dummy gate;
selectively removing said dummy gate relative to said dummy-fill, wherein a gate trench is formed when removing said dummy gate, said gate trench partially exposing an upper surface of said first ferroelectric material; and
forming a spacer structure in said gate trench, said spacer structure covering inner sidewalls of said gate trench;
wherein said second ferroelectric material is formed in alignment with said spacer structure.

15. The method of claim 14, wherein forming said second ferroelectric material comprises performing an implantation process in alignment with said spacer structure and said dummy-fill, wherein dopants are implanted into a portion of said first ferroelectric material in alignment with said spacer structure and said dummy-fill, said doped portion of said first ferroelectric material forming said second ferroelectric material.

16. The method of claim 15, further comprising, after performing said implantation process:
removing said spacer structure; and
depositing a work function adjusting material and a gate electrode material in said gate trench.

17. The method of claim 16, wherein depositing said work function adjusting material comprises conformally depositing a liner of said work function adjusting material.

18. The method of claim 15, wherein said first ferroelectric material comprises a hafnium oxide material, and wherein said implantation process comprises implanting at least one of silicon (Si), zirconium (Zr) and titanium (Ti).

19. The method of claim 15, wherein performing said implantation process comprises implanting silicon at an implantation dose of about 1e16 atoms/cm².

20. A method, comprising:
depositing a first ferroelectric material over a substrate;
performing an implantation process, wherein dopants are implanted into a portion of said deposited first ferroelectric material for forming a portion of doped first ferroelectric material embedded into said deposited first ferroelectric material, wherein said doped first ferroelectric material represents a second ferroelectric material being stacked with said first ferroelectric material in a plane parallel to an upper surface of said substrate; and
forming a gate electrode material over said first and second ferroelectric materials.

21. A method, comprising:
applying a voltage signal to a gate of a semiconductor device; and
coupling a source region and a drain region of said semiconductor device with ground;
wherein said semiconductor device comprises:
a substrate;
a gate structure formed over said substrate, said gate structure comprising a first ferroelectric material having a first remanent polarization and a second ferroelectric material having a second remanent polarization, said first remanent polarization being smaller than said second remanent polarization; and
said source and drain regions formed in said substrate, said source and drain regions being laterally separated by a channel region extending along a length direction below said gate structure;
wherein said first ferroelectric material and said second ferroelectric material are stacked in a plane parallel to an upper surface of said substrate; and
wherein said voltage signal comprises at least a first voltage signal having a voltage peak exceeding a switching voltage at which the orientation of the second remanent polarization is flipped.
